(19) United States
(12) Patent Application Publication
(10) Pub. No.: US 2025/0333838 A1
(43) Pub. Date: Oct. 30, 2025

(54) FILM FORMING METHOD AND FILM FORMING APPARATUS

(71) Applicant: Tokyo Electron Limited, Tokyo (JP)

(72) Inventors: Satoshi ONODERA, Yamanashi (JP); Jun OGAWA, Yamanashi (JP); Yamato TONEGAWA, Yamanashi (JP)

(21) Appl. No.: 19/184,288

(22) Filed: Apr. 21, 2025

(30) Foreign Application Priority Data
Apr. 25, 2024 (JP) 2024-071872

(51) Int. Cl. C23C 16/34; C23C 16/36; C23C 16/44; C23C 16/505; C23C 16/52

(52) U.S. Cl. CPC C23C 16/345; C23C 16/36; C23C 16/4408; C23C 16/505; C23C 16/52

(57) ABSTRACT

To provide a technique capable of controlling film properties, a film forming method according to one embodiment of the present disclosure includes: forming a SiCN layer on a substrate using a first silicon raw material and a first nitriding agent; forming a SiN layer on the SiCN layer using a second silicon raw material and a second nitriding agent; and forming a laminate film in which the SiCN layer and the SiN layer are laminated, by repeating the forming of the SiCN layer and the forming of the SiN layer. The first silicon raw material contains a Si—C—Si bond.

### CROSS-REFERENCE TO RELATED APPLICATION

The present application claims priority under 35 U.S.C. § 119 to Japanese Patent Application No. 2024-071872, filed Apr. 25, 2024, the contents of which are incorporated herein by reference in their entireties.

### BACKGROUND OF THE INVENTION

### Field of the Invention

This disclosure relates to a film forming method and a film forming apparatus.

### Description of the Related Art

A technique for controlling a film stress in a film formed on a substrate is known (see, for example, Japanese Patent Laid-Open Publication No. 2020-145244).

### SUMMARY OF THE INVENTION

The present disclosure provides a technique capable of controlling film properties.

A film forming method according to one embodiment of the present disclosure includes: forming a SiCN layer on a substrate using a first silicon raw material and a first nitriding agent; forming a SiN layer on the SiCN layer using a second silicon raw material and a second nitriding agent; and forming a laminate film in which the SiCN layer and the SiN layer are laminated, by repeating the forming of the SiCN layer and the forming of the SiN layer, wherein the first silicon raw material contains a Si—C—Si bond.

According to the present disclosure, film properties can be controlled.

### BRIEF DESCRIPTION OF THE DRAWINGS

FIG. 1 is a flowchart showing a film forming method according to an embodiment;

FIG. 2 is a flowchart showing an example of a SiCN layer forming step;

FIG. 3 is a flowchart showing an example of a SiN layer forming step;

FIG. 4 is a diagram showing an example of a first silicon raw material;

FIG. 5 is a schematic vertical cross-sectional view showing a film forming apparatus according to an embodiment;

FIG. 6 is a schematic horizontal cross-sectional view showing a film forming apparatus according to an embodiment;

FIG. 7 is a graph showing an example of film stress; and

FIG. 8 is a graph showing an example of film density.

### DETAILED DESCRIPTION OF THE DISCLOSURE

Hereinafter, non-limiting exemplary embodiments of the present disclosure will be described with reference to the attached drawings. In all of the attached drawings, the same or corresponding members or parts will be denoted by the same or corresponding reference numerals, and duplicate descriptions will be omitted.

### [Film Forming Method]

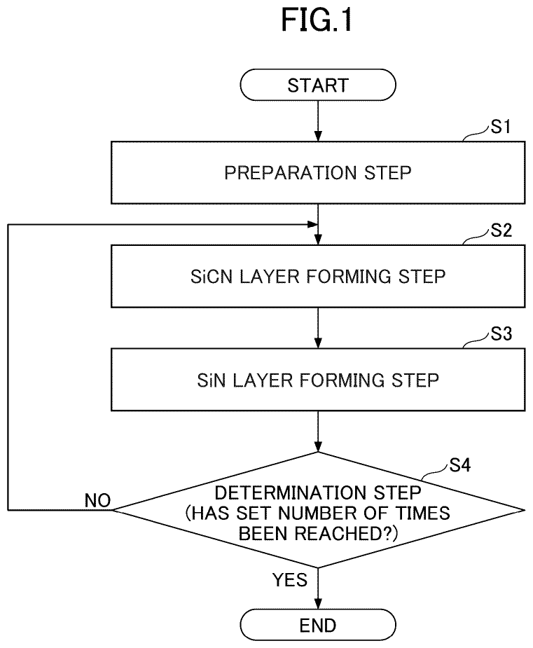

A film forming method according to an embodiment will be described with reference to FIGS. 1 to 4. FIG. 1 is a flowchart showing a film forming method according to an embodiment. As shown in FIG. 1, the film forming method according to the embodiment includes a preparation step S1, a SiCN layer forming step S2, a SiN layer forming step S3, and a determination step S4.

### (Preparation Step S1)

The preparation step S1 includes preparing a substrate. The substrate is, for example, a silicon wafer. The substrate may have a recess, such as a trench and a hole on its surface.

### (SiCN Layer Forming Step S2)

The SiCN layer forming step S2 is performed after the preparation step S1. The SiCN layer forming step S2 includes forming a SiCN layer on the substrate using a first silicon raw material and a first nitriding agent. The SiCN layer forming step S2 is performed at, for example, a first temperature. The first temperature is, for example, 500° C. or higher and 580° C. or lower.

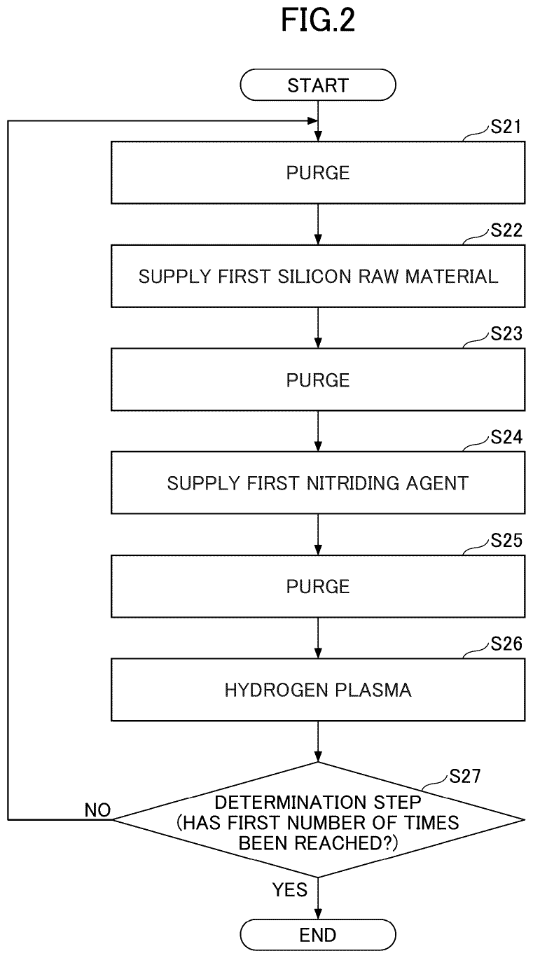

FIG. 2 is a flowchart showing an example of the SiCN layer forming step S2. As shown in FIG. 2, the SiCN layer forming step S2 includes steps S21 to S27.

Step S21 includes performing purging on the surface of the substrate by supplying an inert gas to the surface of the substrate. The inert gas is, for example, nitrogen (N₂) gas. The inert gas may be a noble gas such as helium (He) gas or argon (Ar) gas.

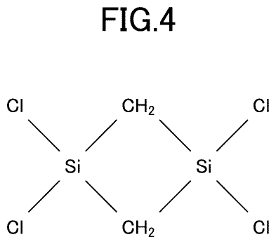

Step S22 is performed after step S21. Step S22 includes supplying the first silicon raw material to the surface of the substrate and adsorbing the first silicon raw material to the surface of the substrate. FIG. 4 is a diagram showing an example of the first silicon raw material. As shown in FIG. 4, the first silicon raw material is, for example, 1,1,3,3-tetrachloro-1,3-disilacyclobutane (Si₂C₂Cl₄H₄). Step S22 may include supplying an inert gas to the surface of the substrate at a lower flow rate than that in step S21. The inert gas is, for example, the same as the inert gas used in step S21.

Step S23 is performed after step S22. Step S23 includes performing purging on the surface of the substrate by supplying an inert gas to the surface of the substrate. The inert gas is, for example, the same as the inert gas used in step S21.

Step S24 is performed after step S23. Step S24 includes thermally treating the substrate in an atmosphere containing the first nitriding agent without providing an RF power, to thermally nitride the first silicon raw material adsorbed to the surface of the substrate. As a result, a SiCN layer is formed on the surface of the substrate. The first nitriding agent is, for example, ammonia (NH₃). Step S24 may include supplying an inert gas to the surface of the substrate at a lower flow rate than that in step S21. The inert gas is, for example, the same as the inert gas used in step S21.

Step S25 is performed after step S24. Step S25 includes performing purging on the surface of the substrate by supplying an inert gas to the surface of the substrate. The inert gas is, for example, the same as the inert gas used in step S21.

Step S26 is performed after step S25. Step S26 includes exposing the substrate to a hydrogen plasma to modify the thermally nitrided first silicon material. Step S26 may include generating the hydrogen plasma by supplying hydrogen gas to the substrate and also supplying an RF power. Step S26 may include supplying an inert gas at the same time as the hydrogen gas. The inert gas is for example, the same as the inert gas used in step S21. Steps S25 and S26 do not need to be performed.

Step S27 is performed after step S26. Step S27 includes determining whether steps S21 to S26 have been performed a first number of times. When it is determined that the number of times these steps have been performed has not reached the first number of times (NO in step S27), steps S21 to S26 are performed again. When it is determined that the number of times these steps have been performed has reached the first number of times (YES in step S27), the SiCN layer forming step S2 is ended. In this way, in the SiCN layer forming step S2, a SiCN layer is formed on the substrate through repetition of steps S21 to S26 until the number of times these steps have been performed has reached the first number of times.

### (SiN Layer Forming Step S3)

The SiN layer forming step S3 is performed after the SiCN layer forming step S2. The SiN layer forming step S3 includes forming a SiN layer on the substrate using a second silicon raw material and a second nitriding agent. The SiN layer forming step S3 is performed at, for example, a second temperature. The second temperature is, for example, 500° C. or higher. In this case, it is easy to form a SiN layer. For example, the second temperature is the same as the first temperature. In this case, it is unnecessary to change the temperature of the substrate when performing the SiN layer forming step S3 after the SiCN layer forming step S2. Therefore, productivity is improved. The second temperature may be different from the first temperature.

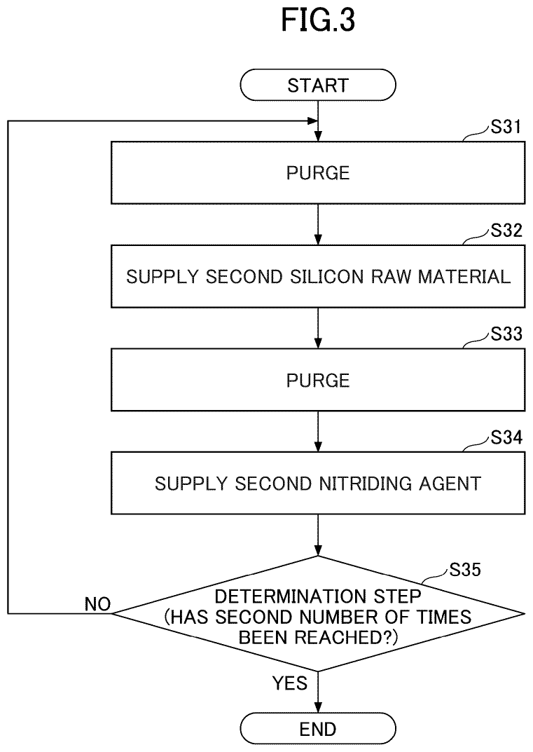

FIG. 3 is a flowchart showing an example of the SiN layer forming step S3. As shown in FIG. 3, the SiN layer forming step S3 includes steps S31 to S35.

Step S31 includes performing purging on the surface of the substrate by supplying an inert gas to the surface of the substrate. The inert gas is, for example, the same as the inert gas used in step S21.

Step S32 is performed after step S31. Step S32 includes supplying a second silicon raw material to the surface of the substrate and adsorbing the second silicon raw material to the surface of the substrate. The second silicon raw material is different from the first silicon raw material. The second silicon raw material is, for example, dichlorosilane (SiH₂Cl₂). Step S32 may include supplying an inert gas to the surface of the substrate at a lower flow rate than that in step S31. The inert gas is, for example, the same as the inert gas used in step S21.

Step S33 is performed after step S32. Step S33 includes performing purging on the surface of the substrate by supplying an inert gas to the surface of the substrate. The inert gas is, for example, the same as the inert gas used in step S21.

Step S34 is performed after step S33. Step S34 includes thermally treating the substrate in an atmosphere containing a second nitriding agent without providing an RF power, to thermally nitride the second silicon material adsorbed to the surface of the substrate in step S32. As a result, a SiN layer is formed on the surface of the substrate. The second nitriding agent is, for example, the same as the first nitriding agent. The second nitriding agent is, for example, ammonia (NH₃). Step S34 may include supplying an inert gas to the surface of the substrate at a lower flow rate than that in step S31. The inert gas is, for example, the same as the inert gas used in step S21.

Step S35 is performed after step S34. Step S35 includes determining whether steps S31 to S34 have been performed a second number of times. When it is determined that the number of times these steps have been performed has not reached the second number of times (NO in step S35), steps S31 to S34 are performed again. When it is determined that the number of times these steps have been performed has reached the second number of times (YES in step S35), the SiN layer forming step S3 is ended. In the SiN layer forming step S3, the SiN layer is formed on the SiCN layer through repetition of steps S31 to S34 until the number of times these steps have been performed has reached the second number of times.

### (Determination Step S4)

The determination step S4 is performed after the SiN layer forming step S3. The determination step S4 includes determining whether the SiCN layer forming step S2 and the SiN layer forming step S3 have been performed a set number of times. When it is determined that the number of times these steps have been performed has not reached the set number of times (NO in the determination step S4), the SiCN layer forming step S2 and the SiN layer forming step S3 are executed again. When it is determined that the number of time these steps have been performed has reached the set number of times (YES in the determination step S4), the process flow is ended. Thus, in the film forming method according to the embodiment, a laminate film in which SiCN layers and SiN layers are laminated is formed through repetition of the SiCN layer forming step S2 and the SiN layer forming step S3 until the number of times these steps have been performed has reached the set number of times.

As described above, the film forming method according to the embodiment includes the SiCN layer forming step S2, the SiN layer forming step S3, and the determination step S4. In the SiCN layer forming step S2, a SiCN layer is formed on the substrate using 1,1,3,3-tetrachloro-1,3-disilacyclobutane, which is an example of the first silicon raw material, and ammonia, which is an example of the first nitriding agent. In the SiN layer forming step S3, a SiN layer is formed on the SiCN layer using dichlorosilane, which is an example of the second silicon raw material, and ammonia, which is an example of the second nitriding agent. In the determination step S4, the SiCN layer forming step S2 and the SiN layer forming step S3 are repeated. In this case, by controlling the first number of times in the SiCN layer forming step S2 and the second number of times in the SiN layer forming step S3, it is possible to adjust the ratio between SiCN layers and SiN layers contained in the laminate film, and to control the film properties of the laminate film.

### [Film Forming Apparatus]

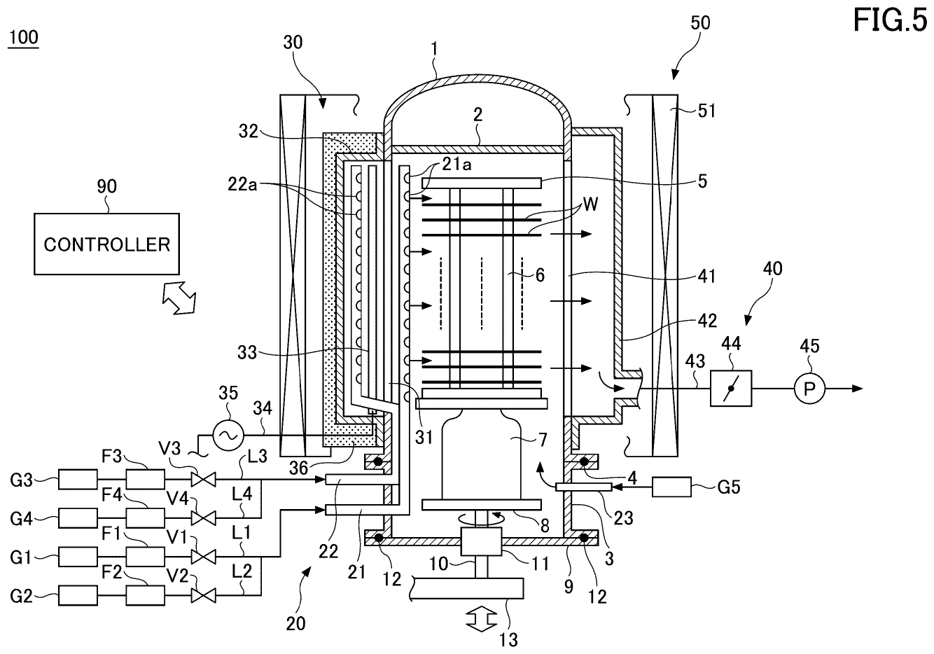

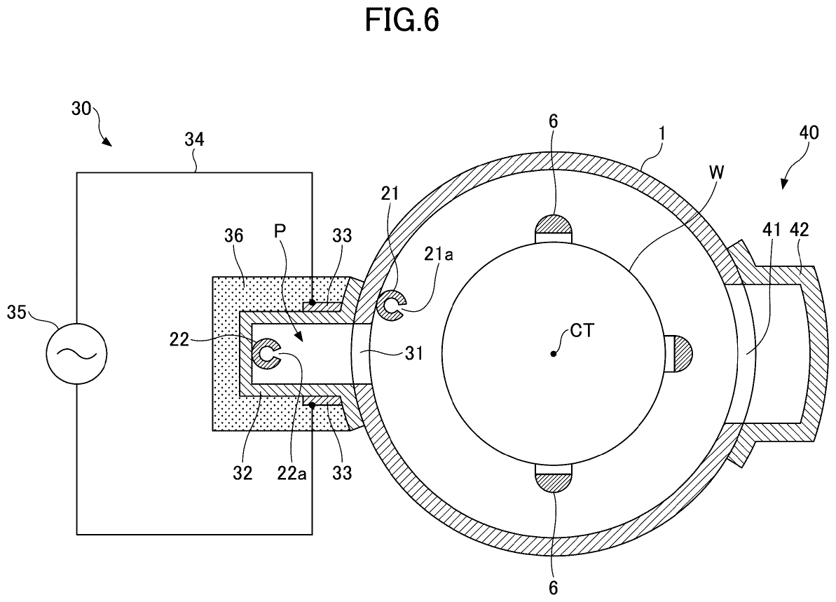

A film forming apparatus 100 according to an embodiment will be described with reference to FIGS. 5 and 6. FIG. 5 is a schematic vertical cross-sectional view showing a film forming apparatus 100 according to an embodiment. FIG. 6 is a schematic horizontal cross-sectional view showing the film forming apparatus 100 according to the embodiment. As shown in FIGS. 5 and 6, the film forming apparatus 100 includes a processing chamber 1, a gas supply part 20, a plasma generation part 30, a gas exhaust part 40, a heating part 50, and a controller 90.

The processing chamber 1 has a ceilinged longitudinal cylindrical shape opened at the lower end. The processing chamber 1 is formed of, for example, quartz. A ceiling plate 2 is provided in the processing chamber 1 near the upper end of the processing chamber 1, and a region under the ceiling plate 2 is sealed. The ceiling plate 2 is formed of, for example, quartz. A cylindrical metallic manifold 3 is connected to the opening at the lower end of the processing chamber 1 via a seal member 4. The seal member 4 is, for example, an O-ring.

The manifold 3 supports the lower end of the processing chamber 1. A boat 5 is inserted into the processing chamber 1 from under the manifold 3. The boat 5 holds a plurality of (for example, 25 to 150) substrates W substantially horizontally at intervals provided along the vertical direction. The boat 5 is formed of, for example, quartz. The boat 5 has, for example, three supports 6, and the plurality of substrates W are supported in grooves formed in the supports 6.

The boat 5 is placed on a rotating table 8 via a thermal insulating cylinder 7. The thermal insulating cylinder 7 is formed of, for example, quartz. The thermal insulating cylinder 7 restricts heat dissipation from the opening at the lower end of the manifold 3. The rotating table 8 is supported on a rotation shaft 10. The opening at the lower end of the manifold 3 is opened and closed by a cover 9. The cover 9 is formed of, for example, a metal material, such as stainless steel and the like. The rotation shaft 10 penetrates the cover 9.

A magnetic fluid seal 11 is provided at the part penetrated by the rotation shaft 10. The magnetic fluid seal 11 airtightly seals and rotatably supports the rotation shaft 10. A seal member 12 is provided between the periphery of the cover 9 and the lower end of the manifold 3 for maintaining airtightness in the processing chamber 1. The seal member 12 is, for example, an O-ring.

The rotation shaft 10 is attached to an end of an arm 13 supported by a lifting mechanism, such as a boat elevator and the like. When the arm 13 is moved upward or downward, the boat 5, the thermal insulating cylinder 7, the rotating table 8, and the cover 9 are moved upward or downward integrally with the rotation shaft, to be inserted into or removed from the processing chamber 1.

The gas supply part 20 supplies various gases into the processing chamber 1. The gas supply part 20 includes, for example, a gas nozzle 21, a gas nozzle 22, and a gas nozzle 23. The gas nozzle 21, the gas nozzle 22, and the gas nozzle 23 are formed of, for example, quartz. The gas supply part 20 may further include another gas nozzle.

The gas nozzle 21 has an L-letter shape that penetrates the side wall of the manifold 3 inward, and is bent upward and extends vertically. A vertical part of the gas nozzle 21 is provided in the processing chamber 1. A plurality of gas holes 21a are provided in the vertical part of the gas nozzle 21. The plurality of gas holes 21a are provided at predetermined intervals along the extending direction of the gas nozzle 21. Each gas hole 21a is oriented to, for example, the center CT of the processing chamber 1.

A supply path L1 is connected to the gas nozzle 21. The supply path L1 is provided with a supply source G1 of 1,1,3,3-tetrachloro-1,3-disilacyclobutane, a mass flow controller F1, and an opening/closing valve V1 in order from the upstream side to the downstream side in the gas flow direction. 1,1,3,3-tetrachloro-1,3-disilacyclobutane is an example of the first silicon raw material. The supply timing of 1,1,3,3-tetrachloro-1,3-disilacyclobutane in the supply source G1 is controlled by the opening/closing valve V1, and the flow rate thereof is adjusted to a predetermined flow rate by the mass flow controller F1. 1,1,3,3-tetrachloro-1,3-disilacyclobutane flows into the gas nozzle 21 through the supply path L1 and is discharged horizontally from the plurality of gas holes 21a toward the center CT of the processing chamber 1.

A supply path L2 is connected to the gas nozzle 21. The supply path L2 may be connected to the supply path L1 at the downstream of the opening/closing valve V1. The supply path L2 is provided with a supply source G2 of dichlorosilane, a mass flow controller F2, and an opening/closing valve V2 in order from the upstream side to the downstream side in the gas flow direction. Dichlorosilane is an example of the second silicon raw material. The supply timing of dichlorosilane in the supply source G2 is controlled by the opening/closing valve V2, and the flow rate thereof is adjusted to a predetermined flow rate by the mass flow controller F2. Dichlorosilane flows into the gas nozzle 21 through the supply path L2, and is discharged horizontally from the plurality of gas holes 21a toward the center CT of the processing chamber 1.

The gas nozzle 22 has an L-letter shape that penetrates the side wall of the manifold 3 inward, and is bent upward and extends vertically. A vertical part of the gas nozzle 22 is provided in a plasma generation space P described later. A plurality of gas holes 22a are provided in the vertical part of the gas nozzle 22. The plurality of gas holes 22a are provided at predetermined intervals along the extending direction of the gas nozzle 22. Each gas hole 22a is oriented to, for example, the center CT of the processing chamber 1.

A supply path L3 is connected to the gas nozzle 22. The supply path L3 is provided with a supply source G3 of ammonia, a mass flow controller F3, and an opening/closing valve V3 in order from the upstream side to the downstream side in the gas flow direction. Ammonia is an example of the first nitriding agent and the second nitriding agent. The supply timing of ammonia in the supply source G3 is controlled by the opening/closing valve V3, and the flow rate thereof is adjusted to a predetermined flow rate by the mass flow controller F3. Ammonia flows into the gas nozzle 22 through the supply path L3, and is discharged horizontally from the plurality of gas holes 22a toward the center CT of the processing chamber 1.

A supply path L4 is connected to the gas nozzle 22. The supply path L4 may be connected to the supply path L3 at a location downstream of the opening/closing valve V3. The supply path L4 is provided with a supply source G4 of a hydrogen gas, a mass flow controller F4 and an opening/closing valve V4 in order from the upstream side to the downstream side in the gas flow direction. The supply timing of the hydrogen gas in the supply source G4 is controlled by the opening/closing valve V4, and the flow rate thereof is adjusted to a predetermined flow rate by the mass flow controller F4. The hydrogen gas flows into the gas nozzle 22 through the supply path L4 and is discharged horizontally from the plurality of gas holes 22a toward the center CT of the processing chamber 1.

The gas nozzle 23 has a straight tube shape that penetrates the side wall of the manifold 3 and extends horizontally. The gas nozzle 23 is connected to a supply source G5 of an inert gas. An end part of the gas nozzle 23 is provided in the processing chamber 1. The end part of the gas nozzle 23 is opened, and the inert gas is supplied into the processing chamber 1 through the opening.

The plasma generation part 30 is provided on a part of the side wall of the processing chamber 1. The plasma generation part 30 generates a plasma from the hydrogen gas supplied from the gas nozzle 22. The plasma generation part 30 includes a plasma partition wall 32, a pair of plasma electrodes 33, a power supply line 34, an RF power source 35, and an insulating protection cover 36.

The plasma partition wall 32 is airtightly welded to the outer wall of the processing chamber 1. The plasma partition wall 32 is formed of, for example, quartz. The plasma partition wall 32 has a box cross-sectional shape and covers an opening 31 formed in the side wall of the processing chamber 1. The opening 31 is formed in an elongated shape extending in the vertical direction so as to be able to cover all the substrates W supported by the boat 5 in the vertical direction. The gas nozzle 22 is set in the plasma generation space P, which is an inner space defined by the plasma partition wall 32 and communicating with the interior of the processing chamber 1. The gas nozzle 21 is provided at a location close to the substrates W and extending along the inner wall of the processing chamber 1 outside the plasma generation space P.

The pair of plasma electrodes 33, each of which has an elongated shape, are situated on the outer surfaces of walls of the plasma partition wall 32 on facing sides, such that the pair of plasma electrodes 33 extend along the vertical direction and face each other. The power supply line 34 is connected to the lower end of each plasma electrode 33.

The power supply line 34 electrically connects each plasma electrode 33 and the RF power source 35. For example, one end of the power supply line 34 is connected to the lower end of each plasma electrode 33 on the side of a shorter side of the plasma electrode 33, and the other end of the power supply line 34 is connected to the RF power source 35.

The RF power source 35 is electrically connected to the lower end of each plasma electrode 33 through the power supply line 34. The RF power source 35 supplies an RF power of, for example, 13.56 MHz to the pair of plasma electrodes 33. Thus, an RF power is applied to the plasma generation space P defined by the plasma partition wall 32.

The insulating protection cover 36 is mounted on the outer side of the plasma partition wall 32 so as to cover the plasma partition wall 32. A refrigerant path (not shown) is provided inside the insulating protection cover 36. The plasma electrodes 33 are cooled by flowing a cooled refrigerant, such as nitrogen gas or the like, through the refrigerant path. A shield (not shown) may be provided between the plasma electrodes 33 and the insulating protection cover 36 so as to cover the plasma electrodes 33. The shield is formed of, for example, a good conductor, such as a metal or the like, and is electrically grounded.

The gas exhaust part 40 has a gas exhaust port 41. The gas exhaust port 41 is provided in a side wall part of the processing chamber 1 facing the opening 31. The gas exhaust port 41 is formed in an elongated shape extending vertically so as to match the boat 5. A cover member 42 formed in a U-letter cross-sectional shape so as to cover the gas exhaust port 41 is attached to a part of the processing chamber 1 corresponding to the gas exhaust port 41. The cover member 42 extends upward along the side wall of the processing chamber 1. A gas exhaust pipe 43 is connected to a lower part of the cover member 42. The gas exhaust pipe 43 is provided with a pressure regulating valve 44 and a vacuum pump 45 in order from the upstream to the downstream in the gas flow direction. The gas exhaust part 40 operates the pressure regulating valve 44 and the vacuum pump 45 based on the control of the controller 90, to regulate the pressure in the processing chamber 1 by the pressure regulating valve 44 while aspiring the gas in the processing chamber 1 into the vacuum pump 45.

The heating part 50 includes a heater 51. The heater 51 has a cylindrical shape surrounding the processing chamber 1 on the outer side of the processing chamber 1 in the radial direction. The heater 51 heats each substrate W contained in the processing chamber 1 by heating the entire lateral circumference of the processing chamber 1.

The controller 90 is an electronic circuit, such as a Central Processing Unit (CPU), a Field Programmable Gate Array (FPGA), an Application Specific Integrated Circuit (ASIC), and the like. The controller 90 performs various control operations described in this specification by executing instruction codes stored in a memory or by being designed as a circuit for a special application.

### [Operation of Film Forming Apparatus]

The operation of the film forming apparatus 100 when the film forming method according to the embodiment is performed in the film forming apparatus 100 will be described below.

First, the controller 90 raises the arm 13 to load the boat 5 holding a plurality of substrates W into the processing chamber 1, and airtightly closes and seals the opening at the lower end of the processing chamber 1 with the cover 9. Next, the controller 90 controls the gas exhaust part 40 such that the interior of the processing chamber 1 is at a set pressure, and controls the heating part 50 such that the substrates W become the first temperature.

Next, the controller 90 controls each part of the film forming apparatus 100 so as to perform the SiCN layer forming step S2, the SiN layer forming step S3, and the determination step S4. Thus, a laminate film in which SiCN layers and SiN layers are laminated is formed on each substrate W. The controller 90 adjusts the ratio between the SiCN layers and the SiN layers contained in the laminate film by controlling the first number of times in the SiCN layer forming step S2 and the second number of times in the SiN layer forming step S3. Thus, the film properties of the laminate film can be controlled.

Next, the controller 90 raises the pressure in the processing chamber 1 to the open-air pressure, lowers the temperature in the processing chamber 1 to an unloading temperature, and then lowers the arm 13 to unload the boat 5 from the processing chamber 1. As a result, the processing of the plurality of substrates W is completed.

### [Experimental Results]

In an experiment, laminate films were formed on substrates by performing the preparation step S1, the SiCN layer forming step S2, the SiN layer forming step S3, and the determination step S4 in this order in the film forming apparatus 100, and the film stress and the film density of the formed laminate films were measured. In the experiment, the laminate films were formed under a plurality of conditions between which the ratio between the first number of times in the SiCN layer forming step S2 and the second number of times in the SiN layer forming step S3 (hereinafter referred to as “SiCN:SiN”) was varied (i.e., SiCN:SiN=1:0, 1:1, 1:3, and 0:1). SiCN:SiN=1:0 means a condition in which the SiCN layer forming step S2 was performed and the SiN layer forming step S3 was not performed. SiCN:SiN=0:1 means a condition in which the SiCN layer forming step S2 was not performed and the SiN layer forming step S3 was performed. The conditions of the SiCN layer forming step S2 and the SiN layer forming step S3 are as follows.

### (SiCN Layer Forming Step S2)

Substrate temperature: 550° C.
First silicon raw material: 1,1,3,3-tetrachloro-1,3-disilacyclobutane
First nitriding agent: ammonia

### (SiN Layer Forming Step S3)

Substrate temperature: 550° C.
Second silicon raw material: dichlorosilane
Second nitriding agent: ammonia

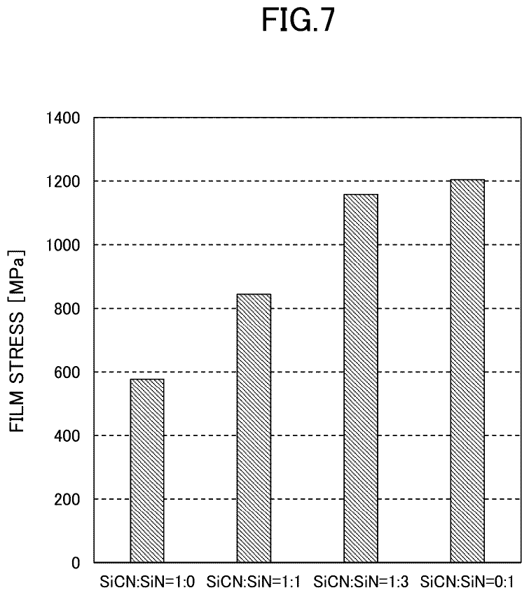

FIG. 7 is a graph showing an example of film stress. In order from the left, the graph of FIG. 7 shows the film stress [MPa] of laminate films in the cases of SiCN:SiN being 1:0, 1:1, 1:3, and 0:1.

As shown in FIG. 7, it can be seen that varying SiCN:SiN resulted in variation in the film stress of the laminate films. From this result, it can be regarded that the film stress of a laminate film can be controlled by controlling the ratio between the first number of times in the SiCN layer forming step S2 and the second number of times in the SiN layer forming step S3.

As shown in FIG. 7, in the case of SiCN:SiN=1:3, the film stress of the laminate film was 1, 158 MPa. From this result, it can be regarded to be possible to form a laminate film having a high film stress (for example, a film stress higher than 1 GPa) at a low temperature of 550° C. or lower, by laminating SiCN layers formed in the SiCN layer forming step S2 and SiN layers formed in the SiN layer forming step S3.

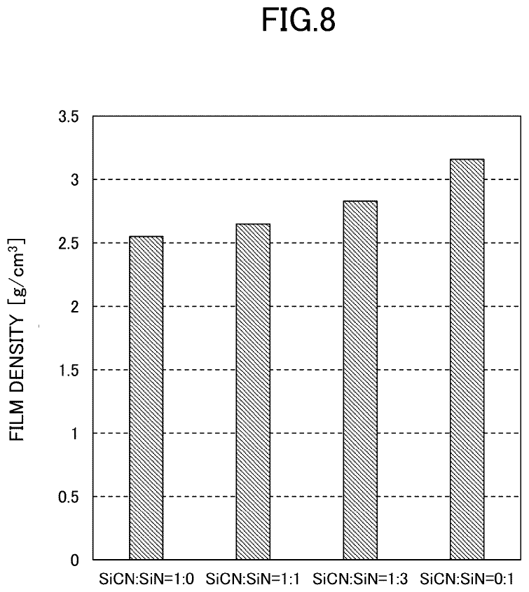

FIG. 8 is a graph showing an example of film density. In order from the left, the graph of FIG. 8 shows the film density [g/cm³] of laminate films in the cases of SiCN:SiN being 1:0, 1:1, 1:3, and 0:1.

As shown in FIG. 8, it can be seen that varying SiCN:SiN resulted in variation in the film density of the laminate films. From this result, it can be regarded that the film density of the laminate film can be controlled by controlling the ratio between the first number of times in the SiCN layer forming step S2 and the second number of times in the SiN layer forming step S3.

As shown in FIG. 8, in the case of SiCN:SiN=1:3, the film density of the laminate film was 2.83 g/cm³. From this result, it can be regarded to be possible to form a laminate film having a high film density at a low temperature of 550° C. or lower, by laminating SiCN layers formed in the SiCN layer forming step S2 and SiN layers formed in the SiN layer forming step S3.

The embodiments disclosed herein should be considered exemplary and non-limiting in all respects. Various omissions, substitutions, and modifications are applicable to the above embodiments without departing from the scope and spirit of the appended claims.

In the above embodiment, a case where the first silicon raw material is 1,1,3,3-tetrachloro-1,3-disilacyclobutane has been described. However, the present disclosure is not limited to this. The first silicon raw material needs only to contain a Si—C—Si bond. For example, 1,1,3,3-tetrachloro-1,3-disilacyclopentane (C₃H₆Cl₄Si₂) may be used as the first silicon raw material. That is, the shape of the cyclic structure composed of silicon (Si) and carbon (C) contained in the first silicon raw material is not limited to a square shape. Moreover, the cyclic structure is not limited to the case where silicon (Si) and carbon (C) are bonded alternately. In addition, 1,1,3,3-tetrafluoro-1,3-disilacyclobutane (C₂H₄F₄Si₂) may be used as the first silicon raw material. That is, the first silicon raw material may contain any halogen other than chlorine (Cl), such as fluorine (F), bromine (Br), iodine (I), and the like.

In the above embodiment, a case where the second silicon raw material is dichlorosilane (SiH₂Cl₂) has been described. However, the present disclosure is not limited to this. The second silicon raw material needs only to be a halogen-containing silicon. As the halogen-containing silicon, fluorine-containing silicon, such as SiF₄, SiHF₃, SiH₂F₂, SiH₃F, and the like, chlorine-containing silicon gas, such as SiCl₄, SiHCl₃, SiH₂Cl₂, SiH₃Cl, Si₂Cl₆, and the like, bromine-containing silicon gas, such as SiBr₄, SiHBr₃, SiH₂Br₂, SiH₃Br, and the like, and combinations thereof can be used.

In the above embodiment, a case where the first nitriding agent and the second nitriding agent are ammonia (NH₃) has been described. However, the present disclosure is not limited to this. As the first nitriding agent and the second nitriding agent, ammonia (NH₃), diazene (N₂H₂), hydrazine (N₂H₄), monomethylhydrazine (CH₃(NH)NH₂), and combinations thereof can be used. The first nitriding agent and the second nitriding agent may be the same or different.

In the above embodiments, a case where the film forming apparatus is a batch-type apparatus for processing a plurality of substrates at a time has been described. However, the present disclosure is not limited to this. For example, the film forming apparatus may be a single wafer-type apparatus for processing one substrate at a time.

What is claimed is:

1. A film forming method, comprising:
forming a SiCN layer on a substrate using a first silicon raw material and a first nitriding agent;
forming a SiN layer on the SiCN layer using a second silicon raw material and a second nitriding agent; and
forming a laminate film in which the SiCN layer and the SiN layer are laminated, by repeating the forming of the SiCN layer and the forming of the SiN layer,
wherein the first silicon raw material contains a Si—C—Si bond.

2. The film forming method according to claim 1,
wherein the forming of the SiCN layer includes:
supplying the first silicon raw material to the substrate;
supplying the first nitriding agent to the substrate; and
performing the supplying of the first silicon raw material and the supplying of the first nitriding agent a first number of times,
wherein the forming of the SiN layer includes:
supplying the second silicon raw material to the substrate;
supplying the second nitriding agent to the substrate; and
performing the supplying of the second silicon raw material and the supplying of the second nitriding agent a second number of times, and
wherein the forming of the laminate film includes controlling a film stress of the laminate film by controlling the first number of times and the second number of times.

3. The film forming method according to claim 1,
wherein the forming of the SiCN layer is performed at a temperature of 500° C. or higher and 580° C. or lower.

4. The film forming method according to claim 1,
wherein the forming of the SiCN layer includes exposing the substrate to a plasma generated from hydrogen gas.

5. The film forming method according to claim 1,
wherein the first silicon raw material is 1,1,3,3-tetrachloro-1,3-disilacyclobutane.

6. The film forming method according to claim 1,
wherein the second silicon raw material is dichlorosilane.

7. The film forming method according to claim 1,
wherein the first nitriding agent and the second nitriding agent are ammonia.

8. A film forming apparatus, comprising:
a processing chamber configured to contain a substrate;
a gas supply part configured to supply a first silicon raw material, a second silicon raw material, a first nitriding agent, and a second nitriding agent into the processing chamber; and
a controller;
wherein the first silicon raw material contains a Si—C—Si bond, and
wherein the controller controls the gas supply part to perform:
forming a SiCN layer on the substrate using the first silicon raw material and the first nitriding agent;
forming a SiN layer on the SiCN layer using the second silicon raw material and the second nitriding agent; and
forming a laminate film in which the SiCN layer and the SiN layer are laminated, by repeating the forming of the SiCN layer and the forming of the SiN layer.
